(19) United States
(12) Patent Application Publication
(10) Pub. No.: US 2026/0123424 A1
(43) Pub. Date: Apr. 30, 2026

(54) LIQUID COOLING FOR INTEGRATED CIRCUIT PACKAGES

(71) Applicant: Intel Corporation, Santa Clara, CA (US)

(72) Inventors: Sami Mohammed Alelyani, Phoenix, AZ (US); Akshay Arun Phadnis, Mesa, AZ (US); Joseph Blane Petrini, Gilbert, AZ (US); Joseph Bautista, Phoenix, AZ (US); Mukund Ayalasomayajula, Chandler, AZ (US)

(73) Assignee: Intel Corporation, Santa Clara, CA (US)

(21) Appl. No.: 19/433,783

(22) Filed: Dec. 27, 2025

(51) Int. Cl. H10W 40/47; H10W 90/00

(52) U.S. Cl. CPC H10W 40/47; H10W 90/726

(57) ABSTRACT

Thermally conductive structures extending from a surface of an integrated circuit component toward an inner surface of a lid structure are described for use in liquid cooling thermal management solutions. An integrated circuit assembly includes a substrate, one or more components on the substrate, and a lid structure over the components. The lid structure includes a top portion and a sidewall that, with the substrate, define a cavity to receive coolant. Inlet and outlet ports extend through the top portion to route coolant through the cavity. Thermally conductive structures in the cavity extend from the component surface toward the top portion inner surface to increase heat-transfer area and reduce thermal resistance. The structures may include solder bodies, metal pins, pillars with solder bodies, patterned solder layers, or combinations thereof. Multi-component implementations include a single lid defining multiple cavities separated by an internal sidewall.

### BACKGROUND

Integrated circuit components can generate significant heat during operation, and computing devices and systems that contain such components often use thermal management solutions to transfer this heat to the ambient environment. Existing thermal management solutions include conductive heat spreading through metal components and convective heat removal using air or liquid coolants circulated through channels, cold plates, or other fluid passages.

### BRIEF DESCRIPTION OF THE DRAWINGS

FIG. 1A is a top-down view of a first example assembly comprising an integrated circuit component to be cooled with a liquid cooling approach in accordance with any of the embodiments described herein.

FIG. 1B is a cross-sectional view of a first example assembly taken along line A-A of FIG. 1A.

FIG. 1C is a cross-sectional view of a variation of the assembly illustrated in FIGS. 1A-1B, taken along the line A-A of FIG. 1A.

FIG. 2A is a top-down view of a second example assembly comprising integrated circuit components to be cooled with a liquid cooling approach in accordance with any of the embodiments described herein.

FIG. 2B is a cross-sectional view of the second assembly illustrated in FIG. 2A taken along line B-B.

FIGS. 2C-2D are cross-sectional views of first and second variations of the second example assembly illustrated in FIGS. 2A-2B, taken along line B-B.

FIG. 3A is a top-down view of a third example assembly comprising integrated circuit components to be cooled with a liquid cooling approach in accordance with any of the embodiments described herein.

FIG. 3B is a cross-sectional view of the third example assembly illustrated in FIG. 3A taken along line C-C.

FIG. 4A is a top-down view of a fourth example assembly comprising integrated circuit components to be cooled with a liquid cooling approach in accordance with any of the embodiments described herein.

FIG. 4B is a cross-sectional view of the fourth example assembly illustrated in FIG. 4A taken along line D-D.

FIGS. 5A-5F illustrate an example processing sequence for forming thermally conductive structures on a surface of an integrated circuit component.

FIG. 6 is an example method of forming thermally conductive structures on an integrated circuit component.

FIG. 7 is an example method of cooling an integrated circuit component during operation using a liquid-cooled thermal management solution that comprises the thermally conductive structures as described herein.

FIG. 8 is a cross-sectional view of an example integrated circuit structure that may be included in any of the integrated circuit dies included in any of the integrated circuit components described herein.

FIG. 9 is a cross-sectional view of an integrated circuit device assembly that may include any of the integrated circuit components disclosed herein.

FIG. 10 is a block diagram of an example electrical device that may include any of the microelectronic assemblies or integrated circuit components disclosed herein.

### DETAILED DESCRIPTION

In some existing thermal management solutions, integrated circuit components can be cooled using liquid cooling approaches. For example, in one indirect cooling approach, an integrated heat spreader comprises microchannels through which a coolant can flow. This approach can include a thermal interface material (TIM) layer (e.g., silver thermal compound, thermal grease) between the integrated circuit component and the integrated heat spreader, which adds thermal resistance. Another source of thermal resistance in this approach is the base of the heat spreader, which increases as the base thickness increases. Thermal performance in these solutions can further depend on microchannel surface area and pressure drop. Another thermal management solution approach is a direct cooling using jet impingement, where thermal performance depends on jet exit velocity. Such thermal management solutions can require a high-pressure difference across a nozzle and can have regions of lower heat transfer between nozzles. This approach can be costly if the integrated circuit component form factor calls for a complex nozzle design, which can be expensive to manufacture.

Described herein are liquid-cooling technologies in which coolant flows through a cavity defined by a lid structure and a substrate during integrated circuit component operation. In some embodiments, thermally conductive structures extend from a surface of the integrated circuit component toward an inner surface of a top portion of the lid structure. These structures can include solder balls, metal pins, and pillars that include a solder body (e.g., a reflowed solder ball) at an end of the pillar, and can increase heat transfer surface area while reducing thermal resistance between the integrated circuit component and the coolant. In some examples, the thermally conductive structures are formed as an arrangement of balls, pins, pillars, or as a solder thermal interface material preform pattern. In some embodiments, the size, pitch, and/or pattern of these structures are selected based on an expected heat generation map. In some examples, jet impingement cooling is combined with these thermally conductive structures by using one or more nozzles to direct coolant toward one or more regions of an integrated circuit component.

The liquid-cooling technologies described herein can provide one or more of the following advantages. First, they can reduce thermal resistance between an integrated circuit component and coolant by eliminating thermal interface layers and an integrated heat spreader base between the integrated circuit component and the coolant. For example, in typical indirect cooling stacks, a first thermal interface material (TIM) layer can be located between an integrated circuit component and an integrated heat spreader, and a second TIM layer can be located between the integrated heat spreader and another thermal management component (e.g., a heat pipe, cold plate, or other heat exchanger component). By routing coolant through a cavity over the integrated circuit component and using thermally conductive structures to transfer heat directly to the coolant, thermal resistance associated with both of these TIM layers can be reduced or eliminated. Eliminating TIM layers can also improve reliability by avoiding TIM-related defects (e.g., void formation during assembly and/or reflow) that can degrade thermal performance over time. Second, they can reduce the sensitivity of cooling performance to integrated circuit component height differences in multi-component integrated circuit assemblies. Third, the thermally conductive structures can be implemented using established ball grid array (BGA) processes (e.g., solder body formation), pin grid array (PGA) processes (e.g., pin placement/assembly), and solder thermal interface material (STIM) preform and/or patterned solder layer technologies, leveraging existing materials, assembly flows, and tools. Fourth, the thermally conductive structures can be arranged with different pitches and patterns to match expected heat generation, and the cavity flow path can support higher flow rates and increased mixing, such that achieving more turbulent flow (e.g., higher Reynolds number flow) is more practical than in microchannel-based approaches. Fifth, in implementations that integrate jet impingement cooling, the thermally conductive structures can be positioned to increase heat transfer surface area and promote local mixing in regions between adjacent jet nozzles, which can reduce the impact of regions having a lower heat transfer coefficient between nozzles.

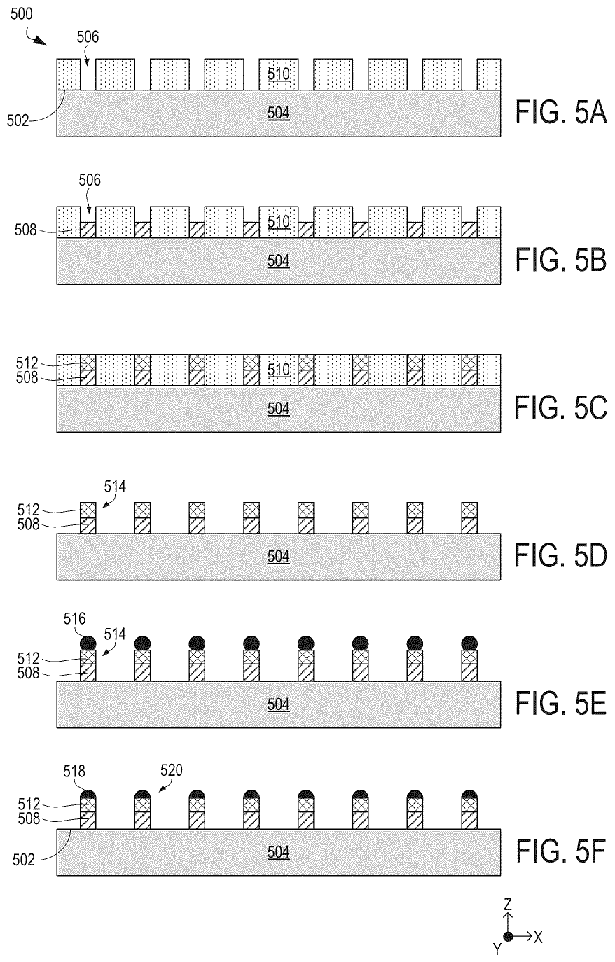

In some embodiments, the thermally conductive structures described herein increase a coolant-wetted heat transfer surface area relative to a bare integrated circuit component surface. For example, the total heat transfer area available for direct heat transfer to coolant (including remaining exposed surface area of the integrated circuit component and surface area of the thermally conductive structures) can be greater than the bare integrated circuit component area. In some embodiments, the total heat transfer area available can be increased by about 2-3× for implementations using solder bodies or solder-grid patterns and by about 5-10× for implementations using pin-type structures (e.g., copper pins). In some demonstrations, an area ratio (total heat transfer area divided by bare integrated circuit component area) of about 1.3 was achieved using thermally conductive structures formed as illustrated in FIGS. 5A-5F.

In the following description, for purposes of explanation, numerous specific details are set forth to provide a thorough understanding of the embodiments. It may be evident, however, that the embodiments can be practiced without these specific details. Well-known circuits, structures, and techniques are not shown in detail so as not to obscure an understanding of this description. Phrases such as “an embodiment,” “various embodiments,” “some embodiments,” and the like are used to indicate that the described features, structures, or characteristics may be included in at least one embodiment, but not every embodiment necessarily includes the particular features, structures, or characteristics. The intention is to cover all modifications, equivalents, and alternatives within the scope of the claims.

Some embodiments may have some, all, or none of the features described for other embodiments. “First,” “second,” “third,” and the like describe a common object and indicate different instances of similar objects being referred to. Such adjectives do not imply that the objects so described must be in a given sequence, either temporally or spatially, in ranking, or in any other manner.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

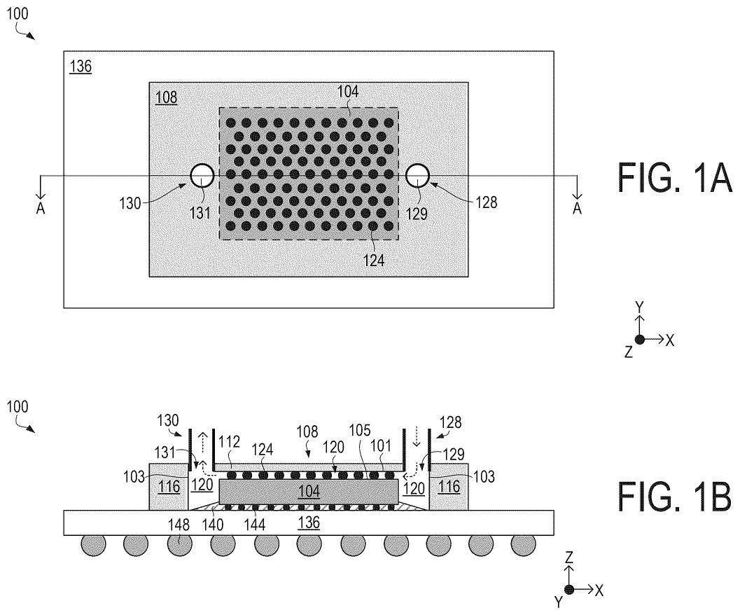

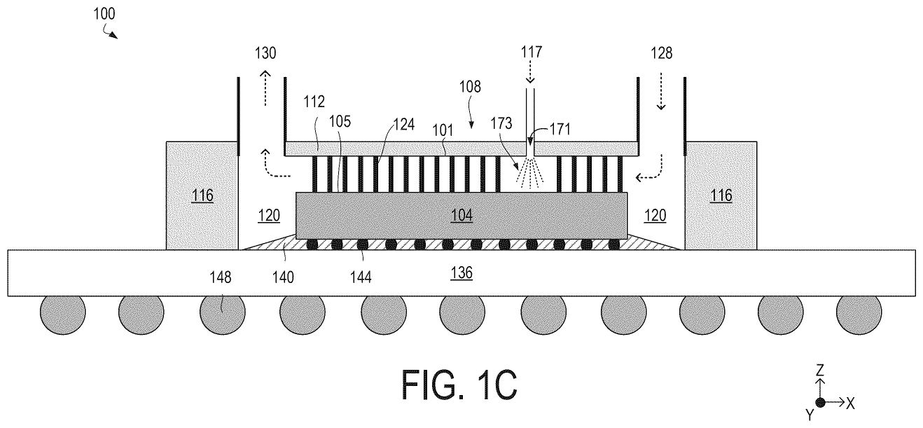

FIG. 1A is a top-down view of a first example assembly comprising an integrated circuit component to be cooled with a liquid cooling approach in accordance with any of the embodiments described herein. The assembly 100 comprises a lid structure 108 positioned over an integrated circuit component 104 that is attached to a substrate 136. In some embodiments, substrate 136 is a printed circuit board (PCB). In other embodiments, substrate 136 is a substrate that comprises a glass core or another structure comprising electrical routing. In the example of FIG. 1A, lid structure 108 comprises a top portion of the lid structure (top portion 112) and a sidewall 116. Sidewall 116 extends from top portion 112 in a direction toward substrate 136 and extends around the integrated circuit component. Top portion 112 comprises an inlet port 128 and an outlet port 130. Inlet port 128 comprises an inlet opening 129 through top portion 112, and outlet port 130 comprises an outlet opening 131 through top portion 112. Inlet port 128 and outlet port 130 may comprise, for example, holes through top portion 112, fittings attached to top portion 112, threaded ports, press-fit ports, or barbed connectors configured to couple to fluid conduits. Lid structure 108 and substrate 136 define a cavity 120 (shown in FIG. 1B) that receives coolant during operation, such that coolant can flow into cavity 120 through inlet opening 129 and flow out of cavity 120 through outlet opening 131, as indicated schematically by the dashed arrows in FIG. 1B.

FIG. 1B is a cross-sectional view of assembly 100 taken along line A-A of FIG. 1A. In the illustrated example, line A-A passes through inlet port 128 (and inlet opening 129), outlet port 130 (and outlet opening 131), a row of thermally conductive structures 124, lid structure 108 (including top portion 112 and sidewall 116), integrated circuit component 104, and substrate 136. As shown in FIG. 1B, cavity 120 is defined by an inner surface 101 of top portion 112, inner surfaces 103 of the sidewall 116, and an upper surface of the substrate 136 around the integrated circuit component 104. The integrated circuit component 104 resides within cavity 120. Inner surface 101 of top portion 112 faces opposite a surface 105 of integrated circuit component 104. Assembly 100 further comprises a plurality of thermally conductive structures 124 located in cavity 120. Thermally conductive structures 124 extend from the surface 105 of integrated circuit component 104 toward inner surface 101 of top portion 112.

In some embodiments, such as shown in FIG. 1B, the thermally conductive structures 124 touch the inner surface 101 of top portion 112. In some embodiments, the thermally conductive structures 124 are spaced from the inner surface 101 of top portion 112 by a small gap, such that coolant flow through the cavity 120 from the inlet opening 129 to the outlet opening 131 is predominantly between and around the plurality of thermally conductive structures 124. In some embodiments, the gap between distal ends of the thermally conductive structures and the inner surface of the top portion is less than a pitch between adjacent thermally conductive structures, such that coolant flow is biased to pass between the thermally conductive structures rather than over the distal ends of the thermally conductive structures. In some embodiments, some of the thermally conductive structures 124 touch the inner surface 101, and some of the thermally conductive structures 124 are spaced from the inner surface 101. In embodiments in which one or more of the thermally conductive structures 124 touch the inner surface 101 of the top portion 112, the contact provides mechanical support that can reduce warpage and/or deflection of the lid structure 108 and/or the integrated circuit component 104.

In some embodiments, inlet opening 129 and outlet opening 131 are spaced from each other along a direction parallel to the surface of integrated circuit component 104 (for example, a left-to-right direction in the view of FIG. 1A). In such embodiments, thermally conductive structures 124 are located between inlet opening 129 and outlet opening 131 along that direction. In some embodiments, thermally conductive structures 124 are arranged in a grid comprising rows and columns. In some embodiments, thermally conductive structures 124 are arranged in a staggered grid in which structures of one row are offset from structures of an adjacent row. In some embodiments, thermally conductive structures 124 comprise a first subset in a first region of the surface of integrated circuit component 104 and a second subset in a second region of the surface of integrated circuit component 104, where the first subset has a first pitch and the second subset has a second pitch different from the first pitch. In some embodiments, the size, pitch, and pattern of thermally conductive structures 124 are selected based on an expected heat generation distribution (e.g., an expected heat generation map or power map) of integrated circuit component 104. For example, thermally conductive structures can have a finer pitch over a “hotspot” region of an integrated circuit component having a higher expected heat generation relative to the pitch of thermally conductive structures over regions of the integrated circuit component having an expected heat generation less than the hotspot region.

Thermally conductive structures 124 may have any suitable geometry and material. In some embodiments, at least one thermally conductive structure 124 comprises a solder material. In some embodiments, the solder material forms substantially ball-shaped bodies (for example, solder bodies formed by placing solder balls and reflowing the solder balls) on a surface of the integrated circuit component. In some embodiments, at least one thermally conductive structure 124 comprises a pillar having a solder body at a distal end (an end distal to the surface of the integrated circuit component) of the pillar (for example, a metallized pillar formed on the surface 105 and a solder body formed on the distal end of the pillar by solder ball placement and reflow). In some embodiments, at least one thermally conductive structure 124 is a metal pin and may comprise copper or another suitable metal. In some embodiments, thermally conductive structures 124 comprise a mix of shapes, such as a first thermally conductive structure that is substantially ball-shaped and a second thermally conductive structure that is pin-shaped, or such as a pillar having a solder body at an end. In some embodiments, at least one thermally conductive structure 124 comprises a solder material layer on the surface 105 of the integrated circuit component 104, where the solder material layer comprises a pattern. In some embodiments, the pattern comprises a grid pattern comprising solder material segments separated by openings.

As used herein, “solder” or “solder material” refers to a fusible metal material that can be melted and solidified to form a bonded joint between two surfaces. In some embodiments, the solder material comprises a solder alloy. Example solder alloys include tin-based alloys, such as tin-lead alloys, tin-silver alloys, tin-copper alloys, tin-bismuth alloys, and tin-silver-copper alloys. In some embodiments, the solder material is lead-free. In some embodiments, the solder material comprises indium or an indium-based alloy. “Solder” and “solder material” are not limited to any particular alloy composition, melting temperature, or manufacturing process.

Lid structure 108 may be formed from any suitable material(s). In some embodiments, top portion 112 comprises a metal (for example, copper, aluminum, stainless steel, or a metal alloy). In some embodiments, sidewall 116 comprises a metal. In some embodiments, sidewall 116 comprises a polymer material. As used herein, “polymer” or “polymer material” refers to a material comprising polymer chains, including thermoplastic materials, thermoset materials, and elastomeric materials, and optionally further comprising one or more fillers, reinforcements, or additives. In some embodiments, lid structure 108 is formed as a single piece. In other embodiments, top portion 112 and sidewall 116 are separate parts that are attached to each other.

In some embodiments, assembly 100 further comprises a seal positioned between sidewall 116 and substrate 136, where the seal surrounds cavity 120. The seal may comprise, for example, an elastomeric gasket, an O-ring, an adhesive, a cured sealant, a solder seal, or another sealing material. The seal can reduce leakage and help route coolant through cavity 120 from inlet opening 129 to outlet opening 131.

Integrated circuit component 104 may be a packaged integrated circuit component or an unpackaged integrated circuit die. In some embodiments, integrated circuit component 104 is electrically and mechanically attached to substrate 136 by a plurality of coupling components 144, which may comprise, for example, solder bumps, microbumps, copper pillars, or other conductive interconnects. In some embodiments, integrated circuit component 104 comprises a device layer and a metallization stack, where the metallization stack is positioned between the device layer and coupling components 144. The metallization stack is a frontside metallization stack as it is formed over the device layer during integrated circuit die processing. Accordingly, the thermally conductive structures 124 can be referred to as backside structures as they are formed on a side of integrated circuit component 104 opposite the frontside metallization stack. In some embodiments, a metal trace of the frontside metallization stack is electrically conductively coupled to a metal trace of substrate 136 at least in part by a coupling component 144. In the example of FIG. 1B, underfill material 140 is positioned at least partially between integrated circuit component 104 and substrate 136, and encompasses coupling components 144.

The underfill material 140 may be any flowable or moldable dielectric material placed between an integrated circuit component and a substrate and then cured or otherwise solidified. The underfill material may comprise a polymer material, such as an epoxy, silicone, polyimide, acrylic, or a combination thereof. The underfill material may comprise one or more fillers, such as silica, alumina, boron nitride, or metal particles, and may be selected to provide a target coefficient of thermal expansion, elastic modulus, and/or thermal conductivity. The underfill material may be introduced as a capillary underfill, a no-flow underfill, a molded underfill, or a pre-applied underfill film, and may be positioned to at least partially surround coupling components between the integrated circuit component and the substrate.

In some embodiments, substrate 136 further comprises solder bumps 148 on a side of substrate 136 opposite the surface of substrate 136 to which integrated circuit component 104 is attached. Solder bumps 148 may be used, for example, to attach substrate 136 to another substrate, an interposer, a motherboard, or another circuit structure. In some embodiments, the substrate 136 is coupled to another structure using one or more of land grid array contacts, conductive pins, conductive pillars, spring contacts, socket contacts, or other suitable contacts in addition to or instead of solder bumps. In other embodiments, conductive couplings other than solder bumps 148 can be used to attach the substrate 136 to another component.

The coolant used in any liquid-cooling solution described herein may be any fluid suitable for removing heat. In some embodiments, the coolant comprises water. In some embodiments, the coolant comprises a water-glycol mixture. In some embodiments, the coolant comprises a dielectric liquid (for example, a synthetic hydrocarbon, silicone-based fluid, fluorinated fluid, or other electrically insulating coolant). In some embodiments, the coolant comprises a liquid configured for single-phase cooling. In some embodiments, the coolant comprises a liquid configured for two-phase cooling (for example, a liquid that can boil in the cavity under operating conditions).

In some embodiments, assembly 100 is part of a larger liquid cooling system. The liquid cooling system may comprise one or more fluid conduits that are fluidically coupled to inlet port 128 and outlet port 130. The liquid cooling system may further comprise a pump and a heat exchanger. In operation, the pump drives coolant through a flow path that includes the inlet port 128, cavity 120, and outlet port 130. As coolant flows through cavity 120, the coolant receives heat from integrated circuit component 104, including heat transferred through thermally conductive structures 124.

As used herein, “fluidically coupled” refers to being connected such that a fluid can be communicated between two structures, either directly or through one or more intermediate structures. A fluidic coupling may be provided by any suitable flow path, including one or more channels, passages, cavities, manifolds, tubes, hoses, pipes, fittings, valves, pumps, connectors, ports, or combinations thereof. A fluidic coupling may be sealed (e.g., to substantially prevent leakage to an external environment) or unsealed, may be permanent or detachable, and may provide a continuous flow path or a selectively openable flow path (e.g., using a valve or quick-disconnect).

After leaving outlet port 130, the coolant can flow through one or more fluid conduits to the heat exchanger, where heat is transferred from the coolant to an ambient environment (for example, to air moved by a fan, or to another coolant loop). The cooled coolant can then return to the pump and be recirculated to inlet port 128. In some embodiments, the pump, the heat exchanger, and at least some of the fluid conduits are enclosed within the same housing that encloses the one or more integrated circuit components being cooled by the liquid cooling system (for example, a housing of a mobile device, a desktop computer, or a server chassis), while in other embodiments one or more of these components are located outside the housing. For example, a rack-level liquid cooling solution can comprise a shared pump and a shared heat exchanger that provide coolant circulation for a plurality of systems installed in a rack. One or more fluid conduits are fluidically coupled between the shared pump and the shared heat exchanger and corresponding inlet and outlet ports of each system, such that coolant is circulated through one or more cavities of each system to cool one or more integrated circuit components in each system.

FIG. 1C is a cross-sectional view of a variation of the assembly illustrated in FIGS. 1A-1B taken along the line A-A of FIG. 1A. In FIG. 1C, the same reference numbers are used for corresponding parts, but thermally conductive structures 124 are implemented as pins rather than solder bodies. In this variation, thermally conductive structures 124 comprise a plurality of metal pins that extend from the surface 105 of integrated circuit component 104 toward the inner surface 101 of top portion 112 within cavity 120. In some embodiments, the pins touch the inner surface 101 of top portion 112, and in other embodiments, the pins are spaced from the inner surface 101 by a gap. In some embodiments, the pins comprise copper. In this variation, instead of leveraging ball grid array (BGA) technology to place solder balls, pin grid array (PGA) technology can be leveraged to provide the pins that make up thermally conductive structures 124. In some embodiments, the pins are attached to the surface 105 by placing individual metal pins onto corresponding metallized attachment sites (e.g., pads or plated regions) using PGA placement tooling, and then securing the pins by solder reflow or brazing to bond the pins to the attachment sites.

FIG. 1C further illustrates a jet impingement structure in lid structure 108. In some embodiments, lid structure 108 comprises a jet inlet 117 fluidically coupled to a nozzle orifice 171. Nozzle orifice 171 is oriented toward the surface 105 of integrated circuit component 104 and directs a jet 173 of coolant into cavity 120 toward the surface 105 during operation. As used herein, a “nozzle” refers to an opening or passage that directs a flow of coolant into the cavity, including a simple orifice, a shaped passage, or a multi-part structure that defines a flow path. In some embodiments, one or more nozzles are formed in top portion 112 of lid structure 108. In some embodiments, the jet impingement structure comprises a jet plate attached to lid structure 108 and comprising a plurality of orifices. In operation, jet 173 can impinge on or flow across the surface of integrated circuit component 104 and around thermally conductive structures 124 to promote local mixing and heat transfer, and coolant can exit cavity 120 through outlet opening 131 and outlet port 130.

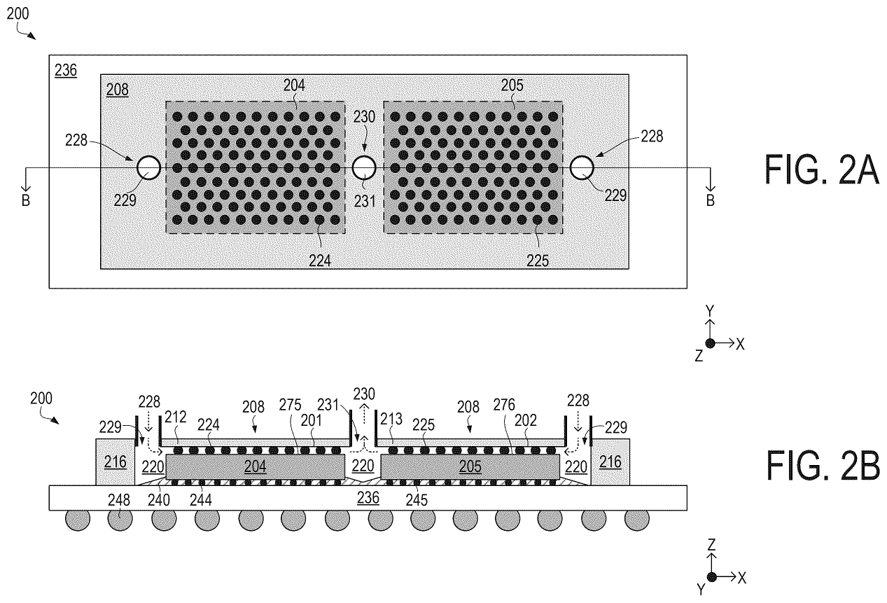

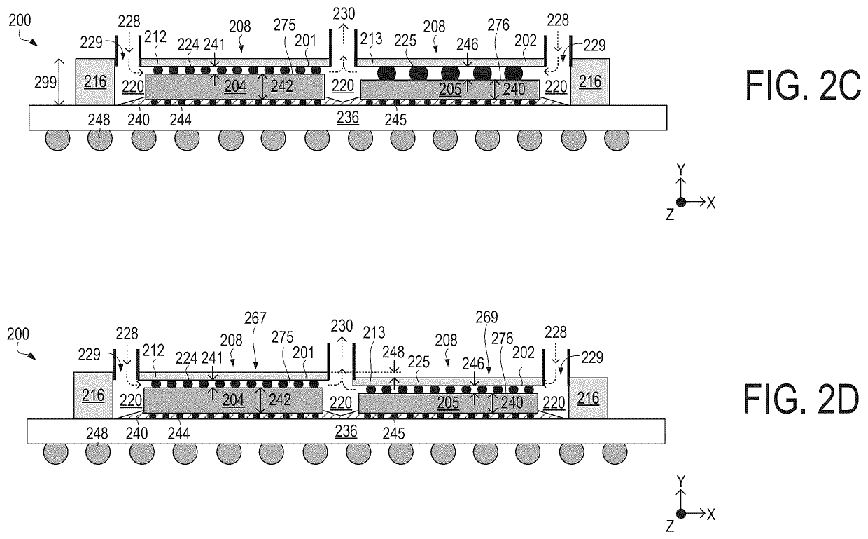

FIG. 2A is a top-down view of a second example assembly comprising integrated circuit components to be cooled with a liquid cooling approach in accordance with any of the embodiments described herein. Assembly 200 is generally similar to assembly 100 of FIGS. 1A-1C, and, unless otherwise indicated, like-numbered elements of FIGS. 2A-2D correspond to and may be implemented similarly to the elements described with respect to FIGS. 1A-1C (e.g., thermally conductive structures 224 correspond to thermally conductive structures 124, lid structure 208 corresponds to lid structure 108).

In FIG. 2A, assembly 200 comprises a lid structure 208 positioned over a first integrated circuit component 204 and a second integrated circuit component 205 that are attached to a substrate 236. Lid structure 208 comprises a top portion and a sidewall 216, where sidewall 216 extends around both integrated circuit components 204 and 205. In the example of FIG. 2A, the top portion comprises a first top portion 212 over integrated circuit component 204 and a second top portion 213 over integrated circuit component 205. Lid structure 208 comprises two inlet ports 228 positioned outside the lateral extent of integrated circuit components 204 and 205 combined and an outlet port 230 positioned between integrated circuit components 204 and 205. Each inlet port 228 comprises an inlet opening 229 through the corresponding top portion, and outlet port 230 comprises an outlet opening 231 through the top portion. Inlet ports 228 and outlet port 230 may comprise, for example, holes through the top portion, fittings attached to the top portion, or other suitable connections to couple to fluid conduits. Although two inlet ports 228 and one outlet port 230 are shown, in other embodiments lid structure 208 comprises any number of inlet ports and outlet ports in any suitable location and arrangement in the top portion of lid structure 208.

FIG. 2B is a cross-sectional view of assembly 200 taken along line B-B of FIG. 2A. In the illustrated example, line B-B passes through inlet ports 228 (and inlet openings 229), outlet port 230 (and outlet opening 231), integrated circuit components 204 and 205, thermally conductive structures 224 and 225, and lid structure 208 (including top portions 212 and 213 and sidewall 216). Lid structure 208 and substrate 236 define a cavity 220 within which integrated circuit components 204 and 205 are located. Inner surface 201 of top portion 212 faces opposite a surface 275 of integrated circuit component 204, and inner surface 202 of top portion 213 faces opposite a surface 276 of integrated circuit component 205.

Assembly 200 comprises a first plurality of thermally conductive structures 224 in cavity 220 over surface 275 of integrated circuit component 204 and a second plurality of thermally conductive structures 225 in cavity 220 over surface 276 of integrated circuit component 205. Thermally conductive structures 224 and 225 extend from the surfaces 275 and 276 toward inner surfaces 201 and 202 of top portions 212 and 213, respectively. In some embodiments, one or more of the thermally conductive structures 224 and/or 225 touch the corresponding inner surface 201 or 202. In some embodiments, one or more of the thermally conductive structures 224 and/or 225 are spaced from the corresponding inner surface 201 or 202 by a gap. Thermally conductive structures 224 and 225 may have any of the sizes, shapes, materials, pitches, heights, and patterns described above with respect to thermally conductive structures 124, including solder bodies (e.g., substantially ball-shaped solder bodies directly attached to an integrated circuit component), pins, pillar structures having solder bodies at distal ends, and solder material layers comprising patterns. In the example of FIG. 2B, thermally conductive structures 224 and 225 are substantially ball-shaped, integrated circuit components 204 and 205 have the same height relative to substrate 236, and thermally conductive structures 224 and 225 have substantially the same height.

In the example of FIG. 2B, coolant flows into cavity 220 through each inlet opening 229 of the two inlet ports 228, flows across regions above integrated circuit components 204 and 205 and around thermally conductive structures 224 and 225, and flows out of cavity 220 through outlet opening 231 of outlet port 230. Stated another way, the inlet ports 228 are positioned outside integrated circuit components 204 and 205 and outlet port 230 is positioned between integrated circuit components 204 and 205, such that coolant enters from opposite sides and exits through a central outlet. In FIGS. 2B-2D, dashed arrows schematically indicate the flow of coolant through inlet ports 228, through cavity 220, and out of outlet port 230. In some embodiments, a coupling component of the coupling components 244 electrically conductively couples a metal trace of a metallization stack of integrated circuit component 204 to a first metal trace in substrate 236, and a coupling component of the coupling components 245 electrically conductively couples a metal trace of a metallization stack of integrated circuit component 205 to a second metal trace in substrate 236.

FIG. 2C is a cross-sectional view of a first variation of the second example assembly illustrated in FIGS. 2A-2B, taken along line B-B of FIG. 2A. In this first variation, integrated circuit components 204 and 205 have different heights. Integrated circuit component 204 has a height 242 that is greater than a height 240 of integrated circuit component 205. Lid structure 208 has a common overall height 299 across both integrated circuit components 204 and 205, such that a first spacing 241 between inner surface 201 of top portion 212 and surface 275 of integrated circuit component 204 is less than a second spacing 246 between inner surface 202 of top portion 213 and surface 276 of integrated circuit component 205. In this example, thermally conductive structures 224 and 225 are substantially ball-shaped, and thermally conductive structures 225 are larger than thermally conductive structures 224 (for example, with a larger maximum lateral dimension and/or a larger height) to account for the larger spacing 246 above integrated circuit component 205.

FIG. 2D is a cross-sectional view of a second variation of the second example assembly illustrated in FIGS. 2A-2B, taken along line B-B of FIG. 2A. In this second variation, integrated circuit components 204 and 205 have different heights (height 242 and height 240), and the spacing between the inner surface of the top portion and the opposing surface of each integrated circuit component is substantially the same. For example, spacing 241 between inner surface 201 and surface 275 is substantially equal to spacing 246 between inner surface 202 and surface 276. In the example of FIG. 2D, thermally conductive structures 224 and 225 are substantially ball-shaped and have substantially the same shape, width, and height. In the example of FIG. 2D, top portions 212 and 213 have substantially the same thickness, which results in an elevation difference 248 between an outer surface portion 267 of top portion 212 and an outer surface portion 269 of top portion 213. In other embodiments, an outer top surface of lid structure 208 is substantially flat, and a thickness of top portion 212 is different from a thickness of top portion 213 to accommodate the different heights of integrated circuit components 204 and 205 while maintaining a target spacing above each integrated circuit component.

The embodiments of FIGS. 2A-2D illustrate that a single lid structure can cover multiple integrated circuit components within a common cavity, and that inlet ports and outlet ports can be arranged to route coolant across multiple integrated circuit components. As noted above, although a single inlet port and a single outlet port are shown in FIGS. 1A-1B and two inlet ports with one outlet port are shown in FIGS. 2A-2D, other embodiments may use any number of inlet ports and outlet ports and may place such ports in any arrangement suitable for a particular integrated circuit layout.

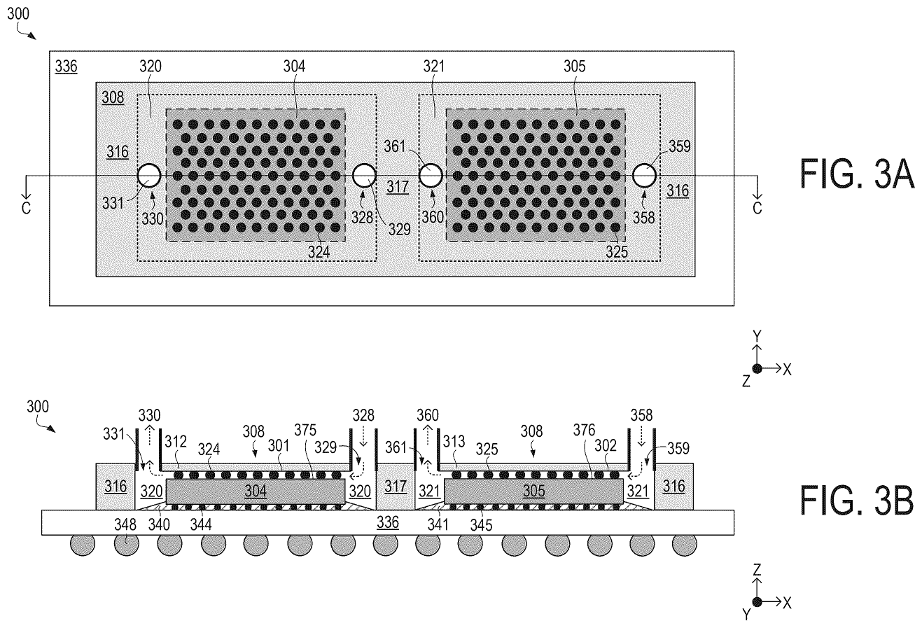

FIG. 3A is a top-down view of a third example assembly comprising integrated circuit components to be cooled with a liquid cooling approach in accordance with any of the embodiments described herein. Assembly 300 is generally similar to assembly 100 of FIGS. 1A-1C, and, unless otherwise indicated, like-numbered elements of FIGS. 3A-3B correspond to and may be implemented similarly to the elements described with respect to FIGS. 1A-IC (e.g., thermally conductive structures 324 correspond to thermally conductive structures 124).

In FIG. 3A, assembly 300 comprises a lid structure 308 positioned over a first integrated circuit component 304 and a second integrated circuit component 305 that are attached to a substrate 336. Lid structure 308 comprises a top portion having a first top portion 312 over integrated circuit component 304 and a second top portion 313 over integrated circuit component 305. Lid structure 308 further comprises an outer sidewall 316 that extends around both integrated circuit components 304 and 305 and an internal sidewall 317 between integrated circuit components 304 and 305. The internal sidewall 317 can separate coolant flow regions within lid structure 308, such that lid structure 308 and substrate 336 define a first cavity 320 containing integrated circuit component 304 and a second cavity 321 containing integrated circuit component 305, where cavities 320 and 321 are separated by internal sidewall 317. In some embodiments, integrated circuit components 304 and 305 have different heights relative to substrate 336 (e.g., as described above with respect to FIGS. 2C-2D), and lid structure 308 and/or thermally conductive structures 324/325 may be configured to accommodate such height differences.

Lid structure 308 comprises inlet ports and outlet ports fluidically coupled to cavities 320 and 321. In the illustrated example, an inlet port 328 and an outlet port 330 are fluidically coupled to cavity 320, and an inlet port 358 and an outlet port 360 are fluidically coupled to cavity 321. Inlet port 328 includes an inlet opening 329 through top portion 312 to allow coolant to enter cavity 320, and outlet port 330 includes an outlet opening 331 through top portion 312 to allow coolant to exit cavity 320. Inlet port 358 includes an inlet opening 359 through top portion 313 to allow coolant to enter cavity 321, and outlet port 360 includes an outlet opening 361 through top portion 313 to allow coolant to exit cavity 321. In some embodiments, inlet ports 328 and 358 and outlet ports 330 and 360 comprise holes through the top portions, fittings attached to the top portions, threaded ports, press-fit ports, barbed connectors, or other structures configured to couple to one or more fluid conduits.

FIG. 3B is a cross-sectional view of the third example assembly 300 illustrated in FIG. 3A taken along line C-C. In the illustrated example, line C-C passes through inlet ports 328 and 358 (and inlet openings 329 and 359), outlet ports 330 and 360 (and outlet openings 331 and 361), the integrated circuit components 304 and 305, rows of thermally conductive structures 324 and 325, the top portions 312 and 313, the external sidewall 316, and the internal sidewall 317. As shown in FIG. 3B, an inner surface 301 of top portion 312 faces opposite a surface 375 of integrated circuit component 304, and an inner surface 302 of top portion 313 faces opposite a surface 376 of integrated circuit component 305. Thermally conductive structures 324 are located in cavity 320 and extend from surface 375 toward inner surface 301, and thermally conductive structures 325 are located in cavity 321 and extend from surface 376 toward inner surface 302. In some embodiments, one or more of the thermally conductive structures 324 and/or 325 touch the corresponding inner surface 301 or 302, and in other embodiments, one or more of thermally conductive structures 324 and/or 325 are spaced from the corresponding inner surface 301 or 302 by a small gap. In FIG. 3B, dashed arrows schematically indicate the flow of coolant into cavity 320 through inlet port 328, through cavity 320 (including between and around thermally conductive structures 324), and out through outlet port 330, and further schematically indicate the flow of coolant into cavity 321 through inlet port 358, through cavity 321 (including between and around thermally conductive structures 325), and out through outlet port 360.

Thermally conductive structures 324 and 325 may have any of the sizes, shapes, materials, pitches, heights, and patterns described above with respect to thermally conductive structures 124. For example, thermally conductive structures 324 and/or 325 may comprise solder bodies (including substantially ball-shaped solder bodies) directly attached to the integrated circuit component, metal pins (including copper pins), pillar structures having solder bodies at distal ends, a solder material layer comprising a pattern, or combinations thereof. In the example of FIGS. 3A-3B, thermally conductive structures 324 and 325 are substantially ball-shaped and may have substantially the same pitch and height. In other embodiments, one or more properties of thermally conductive structures 324 may differ from one or more properties of thermally conductive structures 325, including shape, height, maximum lateral dimension, pitch, pattern, and/or material, such that the coolant-side heat transfer can be tailored independently for integrated circuit component 304 and integrated circuit component 305.

In some embodiments, substrate 336 comprises metal traces for electrical signal routing, and integrated circuit components 304 and 305 are mechanically and electrically conductively coupled to substrate 336 via respective coupling components 344 and 345, which may comprise solder bumps or other conductive interconnects, as described above with respect to coupling components 144. In the example of FIG. 3B, a first underfill material 340 is positioned at least partially between integrated circuit component 304 and substrate 336 and encompasses the corresponding coupling components 344, and a second underfill material 341 is positioned at least partially between integrated circuit component 305 and substrate 336 and encompasses the corresponding coupling components 345. In some embodiments, a coupling component 344 conductively couples a metal trace of a metallization stack of integrated circuit component 304 to a first metal trace in substrate 336, and a coupling component 345 conductively couples a metal trace of a metallization stack of integrated circuit component 305 to a second metal trace in substrate 336.

The embodiments of FIGS. 3A-3B illustrate that a single lid structure can define multiple cavities for cooling multiple integrated circuit components, and that each cavity can have its own inlet and outlet port(s) to provide separate coolant flow paths. Although FIGS. 3A-3B show one integrated circuit component per cavity, in other embodiments a given cavity can contain multiple integrated circuit components (for example, as described above with respect to FIGS. 2A-2D), and a multi-cavity lid structure may include any number of cavities arranged in any suitable layout. For example, in some embodiments, a cavity contains three integrated circuit components, such as a second integrated circuit component adjacent a first side of a first integrated circuit component and a third integrated circuit component adjacent a second side of the first integrated circuit component. Likewise, although FIGS. 3A-3B show one inlet port and one outlet port per cavity, other embodiments may use any number of inlet ports and outlet ports per cavity and may place such ports in any arrangement suitable for a particular integrated circuit layout and desired coolant flow distribution.

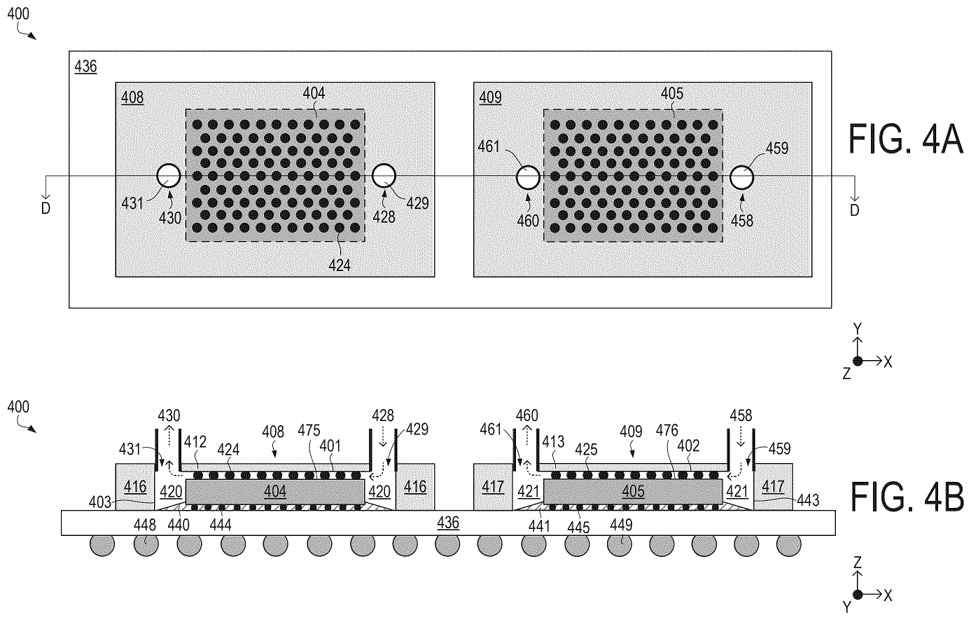

FIG. 4A is a top-down view of a fourth example assembly comprising integrated circuit components to be cooled with a liquid cooling approach in accordance with any of the embodiments described herein. Assembly 400 is generally similar to assembly 300 of FIGS. 3A-3B, and, unless otherwise indicated, like-numbered elements of FIGS. 4A-4B correspond to and may be implemented similarly to the elements described with respect to FIGS. 1A-1C and FIGS. 3A-3B (e.g., cavity 420 corresponds to cavity 120, and thermally conductive structures 424 may be implemented as described above with respect to thermally conductive structures 124).

In FIG. 4A, assembly 400 comprises a substrate 436 supporting a first integrated circuit component 404 and a second integrated circuit component 405. Unlike FIGS. 3A-3B (in which a single lid structure defines multiple cavities), in the example of FIGS. 4A-4B, assembly 400 comprises two separate lid structures that are positioned over respective integrated circuit components 404 and 405. In the illustrated example, a first lid structure 408 is positioned over integrated circuit component 404 and a second lid structure 409 is positioned over integrated circuit component 405. The lid structures 408 and 409 may be similar in structure, although in other embodiments the two lid structures may differ (e.g., in port placement or cavity dimensions). Lid structure 408 comprises a top portion 412 and a sidewall 416 extending from the top portion 412 toward substrate 436 and extending around integrated circuit component 404, and lid structure 409 comprises a top portion 413 and a sidewall 417 extending from the top portion 413 toward substrate 436 and extending around integrated circuit component 405. In some embodiments, integrated circuit components 404 and 405 have different heights, and lid structure 408 and/or thermally conductive structures 424/425 may be configured to accommodate such height differences (e.g., as described above with respect to FIGS. 2C-2D).

Lid structure 408 and the substrate 436 define a cavity 420 within which integrated circuit component 404 is located, and lid structure 409 and the substrate 436 define a cavity 421 within which integrated circuit component 405 is located. Top portion 412 includes an inlet port 428 and an outlet port 430. Inlet port 428 includes an inlet opening 429 through top portion 412 to allow coolant to enter cavity 420, and outlet port 430 includes an outlet opening 431 through top portion 412 to allow coolant to exit cavity 420. Top portion 413 includes an inlet port 458 and an outlet port 460. Inlet port 458 includes an inlet opening 459 through top portion 413 to allow coolant to enter cavity 421, and outlet port 460 includes an outlet opening 461 through top portion 413 to allow coolant to exit cavity 421. In some embodiments, inlet ports 428 and 458 and outlet ports 430 and 460 comprise holes through the corresponding top portions, fittings attached to the corresponding top portions, threaded ports, press-fit ports, barbed connectors, or other connectors configured to couple to one or more fluid conduits. In some embodiments, each lid structure 408 and/or 409 further comprises a seal positioned between sidewall 416 or 417 and substrate 436 and surrounding the corresponding cavity 420 or 421, respectively.

FIG. 4B is a cross-sectional view of assembly 400 taken along line D-D of FIG. 4A. In the illustrated example, line D-D passes through the inlet port 428 (and inlet opening 429) and outlet port 430 (and outlet opening 431) of lid structure 408, the inlet port 458 (and inlet opening 459) and outlet port 460 (and outlet opening 461) of lid structure 409, along with the corresponding sidewalls 416, cavities 420 and 421, integrated circuit components 404 and 405, and substrate 436. As shown in FIG. 4B, cavity 420 is defined by an inner surface 401 of top portion 412, inner surfaces 403 of sidewall 416, and an upper surface of substrate 436, and cavity 421 is defined by an inner surface 402 of top portion 413, inner surfaces 443 of sidewall 417, and the upper surface of substrate 436. Integrated circuit component 404 is located within cavity 420 and includes a surface 475 facing inner surface 401, and integrated circuit component 405 is located within cavity 421 and includes a surface 476 facing inner surface 402.

In some embodiments, cavity 420 includes a plurality of thermally conductive structures 424 located between integrated circuit component surface 475 and inner surface 401, and cavity 421 includes a plurality of thermally conductive structures 425 located between integrated circuit component surface 476 and inner surface 402. Thermally conductive structures 424 and/or 425 may be implemented as described above with respect to thermally conductive structures 124, including solder bodies (e.g., substantially ball-shaped solder bodies) directly attached to an integrated circuit component, metal pins (e.g., copper pins), pillar structures having solder bodies at distal ends, solder material layers comprising a pattern, or combinations thereof. In some embodiments, one or more of the thermally conductive structures 424 touch inner surface 401 and/or one or more of thermally conductive structures 425 touch inner surface 402, and in other embodiments one or more of thermally conductive structures 424 and/or 425 are spaced from the corresponding inner surface 401 or 402 by a small gap such that coolant can flow between the thermally conductive structures and the corresponding inner surface. In some embodiments, thermally conductive structures 424 and/or 425 are arranged in a grid or staggered grid, and in some embodiments the pitch and/or pattern is selected based on an expected heat generation distribution of the corresponding integrated circuit component.

In operation, coolant flows into cavity 420 through inlet opening 429, flows through cavity 420 (including between and around thermally conductive structures 424), receives heat from integrated circuit component 404, and exits through outlet opening 431. Similarly, coolant flows into cavity 421 through inlet opening 459, flows through cavity 421 (including between and around thermally conductive structures 425), receives heat from integrated circuit component 405, and exits through outlet opening 461. In some embodiments, lid structures 408 and 409 are coupled to a common pump and heat exchanger through one or more fluid conduits, such that coolant is circulated through cavities 420 and 421 to cool integrated circuit components 404 and 405. In some embodiments, the two coolant flow paths are configured in parallel (e.g., where coolant is supplied to both inlet ports 428 and 458 and returns from both outlet ports 430 and 460 to a common return line), while in other embodiments the coolant flow paths are configured in series (e.g., where coolant leaving outlet port 430 of lid structure 408 is routed to inlet port 458 of lid structure 409).

In some embodiments, integrated circuit component 404 is mechanically and electrically conductively coupled to substrate 436 by a first plurality of coupling components 444, and integrated circuit component 405 is mechanically and electrically conductively coupled to substrate 436 by a second plurality of coupling components 445. In some embodiments, at least one coupling component 444 is electrically conductively coupled to a first solder ball 448 (or other conductive coupling structure) and at least one coupling component 445 is electrically conductively coupled to a second solder ball 449. In the example of FIG. 4B, a first underfill material 440 is positioned at least partially between integrated circuit component 404 and substrate 436 and encompasses the first plurality of coupling components 444; and a second underfill material 441 is positioned at least partially between integrated circuit component 405 and substrate 436, and encompasses the second plurality of coupling components 445. Coupling components 444/445 and underfill materials 440/441 may be implemented as described above with respect to coupling components 144 and underfill material 140.

The embodiments of FIGS. 4A-4B illustrate that multiple integrated circuit components on a shared substrate can be cooled using separate lid structures, each defining its own cavity and coolant flow path. This arrangement can allow the cooling configuration (e.g., port placement, thermally conductive structure configuration, and flow rate) to be selected independently for each integrated circuit component and can also support modular assembly and replacement of the lid structures for different integrated circuit layouts.

FIGS. 5A-5F illustrate an example processing sequence for forming thermally conductive structures 520 on a surface of an integrated circuit component. In the illustrated example, thermally conductive structures 520 are formed using a patterned mask, selective metallization to form pillar structures, and solder ball placement and reflow to form solder bodies on distal ends of the pillar structures. The surface of the integrated circuit component could be a backside surface of an integrated circuit die, a package lid, an exposed heat spreader surface, or other outer surface of a packaged or unpackaged integrated circuit component.

FIG. 5A shows a structure 500 after forming a patterned mask layer 510 on a surface 502 of integrated circuit component 504. Mask layer 510 includes a plurality of openings 506 that expose corresponding portions of the surface 502 where the thermally conductive structures are to be formed. In some embodiments, mask layer 510 comprises a polyimide film, photoresist, a hard mask (e.g., silicon nitride or silicon oxide) or other suitable material. Openings 506 may be formed by lithography or other suitable patterning techniques.

FIG. 5B shows structure 500 after selectively forming a first layer 508 on the portions of the surface 502 exposed by openings 506. The first layer 508 comprises a metal or other suitable material. In some embodiments, the first layer 508 is deposited by sputtering. In other embodiments, the first layer 508 is deposited by evaporation, chemical vapor deposition, or another suitable deposition process. FIG. 5C shows structure 500 after formation of a second layer 512 over the first layer 508 in the openings 506. In some embodiments, the second layer 512 is deposited by sputtering or any other suitable deposition process. In some embodiments, the first layer 508 comprises iridium and the second layer 512 comprises gold. The use of gold in the second layer 512 can promote attachment of solder, and the use of iridium in the first layer can promote adhesion of gold in the resulting thermally conductive structures 520.

FIG. 5D shows structure 500 after removing mask layer 510, leaving a plurality of pillar-shaped structures 514 on the surface 502 at the locations of openings 506, where each structure 514 comprises a portion of the first layer 508 and a portion of the second layer 512. FIG. 5E shows structure 500 after placement of solder balls 516 on distal ends of the pillar-shaped structures 514 (distal with respect to the surface 502 of the integrated circuit component 504). The solder balls 516 can be placed using a ball placement tool, pick-and-place equipment, or a stencil- and flux-assisted placement process. FIG. 5F shows structure 500 after reflowing solder balls 516 (e.g., using a BGA reflow process), resulting in reflowed solder bodies 518 bonded to the underlying portions of the second layer 512 and thermally conductive structures 520. After reflow, the solder body 518 may be substantially hemispherical or may remain substantially ball-shaped, wherein the term “substantially hemispherical” refers to a generally dome-shaped solder form factor corresponding to a hemisphere and optionally having a flattened region at the base and/or minor surface irregularities consistent with reflow, assembly loading, and manufacturing variation. As used herein, the term “substantially ball-shaped” includes a rounded, compressed solder form factor having flattened regions at one or both ends (e.g., a “smushed” ball) while retaining an overall rounded lateral profile. Each thermally conductive structure 520 thus includes the pillar-shaped structure 514 and the solder body 518 at a distal end of the pillar-shaped structure 514.

After forming the thermally conductive structures 520, integrated circuit component 504 can be incorporated into an integrated circuit assembly by attaching integrated circuit component 504 to a substrate (if not already attached), and then attaching a lid structure to the substrate over integrated circuit component 504 such that the lid structure and the substrate define a cavity configured to receive coolant. In some embodiments, the processing sequence illustrated in FIGS. 5A-5F can be performed before the integrated circuit component is attached to the substrate to which it will be attached in an end product.

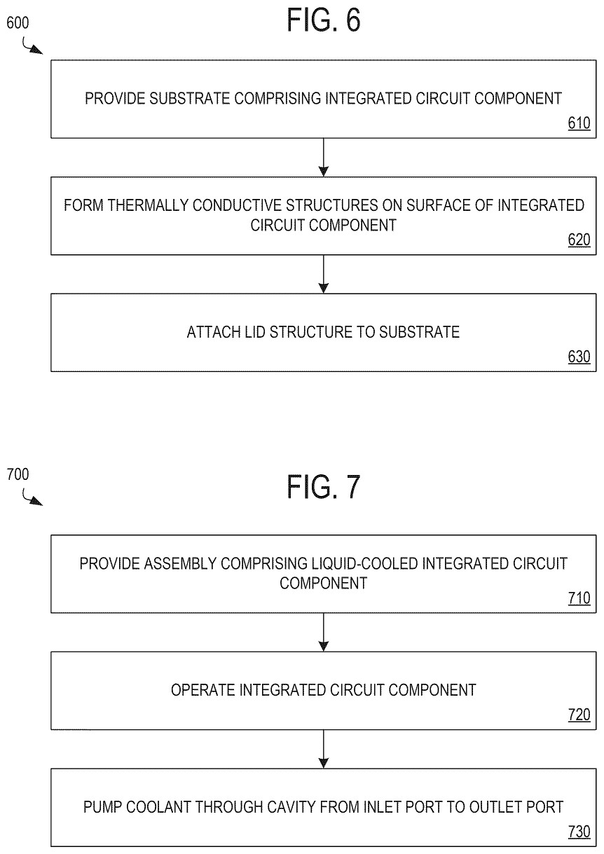

FIG. 6 is an example method of forming thermally conductive structures on an integrated circuit component. Method 600 can be performed by, for example, an integrated circuit manufacturer. At stage 610, a substrate comprising an integrated circuit component located thereon is provided. At stage 620, a plurality of thermally conductive structures is formed on a surface of the integrated circuit component. At stage 630, after forming the plurality of thermally conductive structures, a lid structure is attached to the substrate over the integrated circuit component, the lid structure comprising a top portion and a sidewall, the top portion comprising an inlet port and an outlet port, wherein the lid structure and the substrate define a cavity within which the integrated circuit component is located.

In other embodiments, the method 600 can comprise one or more additional elements. For example, the method 600 can further comprise forming a mask on the surface of the integrated circuit component, the mask comprising a plurality of openings that expose portions of the surface of the integrated circuit component; forming a layer comprising iridium on the portions of the surface of the integrated circuit component; forming a layer comprising gold on the layer comprising iridium; removing the mask, wherein a plurality of pillar-shaped structures remain on the surface of the integrated circuit component after removing the mask, individual pillar-shaped structures of the plurality of pillar-shaped structures comprising a layer comprising gold on a layer comprising iridium; forming a plurality of solder balls on distal ends of the pillar-shaped structures that are distal to the integrated circuit component; and reflowing the plurality of solder balls to form solder bodies at the distal ends of the pillar-shaped structures.

FIG. 7 is an example method of cooling an integrated circuit component during operation using a liquid-cooled thermal management solution that comprises the thermally conductive structures as described herein. Method 700 can be performed by, for example, a data center operator. At stage 710, an apparatus as disclosed in any of the examples described below is provided. At stage 720, the integrated circuit component is operated. At stage 730, a coolant is pumped through the cavity from the inlet port to the outlet port.

In other embodiments, the method 700 can comprise one or more additional elements. For example, pumping the coolant can comprise operating a pump to drive the coolant through one or more fluid conduits fluidically coupled to the inlet port and the outlet port.

As discussed above, one or more integrated circuit components that are cooled by any of the liquid-cooling approaches described herein are attached to a substrate, such as a printed circuit board or a substrate comprising a glass core. In some embodiments, one or more additional integrated circuit components or other components, such as a battery or antenna, can be attached to the substrate. In some embodiments, the substrate can be located in a computing device that comprises a housing that encloses the substrate.

It is to be understood that the drawings illustrate idealized versions of structure cross-sections for purposes of clarity. In actual semiconductor devices, the lines, layers, interfaces, and other elements shown in the drawings may have shapes, contours, and dimensions that differ from those depicted. For example, surfaces illustrated as planar may exhibit undulations, bumps, dishing, or other topography resulting from processing variations; sidewalls may have positive or negative taper; and ninety-degree corners, edges, and ends of features may be rounded or faceted. Likewise, the relative spacing, overlap, and alignment of layers or regions may be greater or less than shown, and features depicted with sharp boundaries may have transition regions or gradients in composition or thickness. Such variations are inherent in semiconductor fabrication and are intended to fall within the scope of the structures described herein.

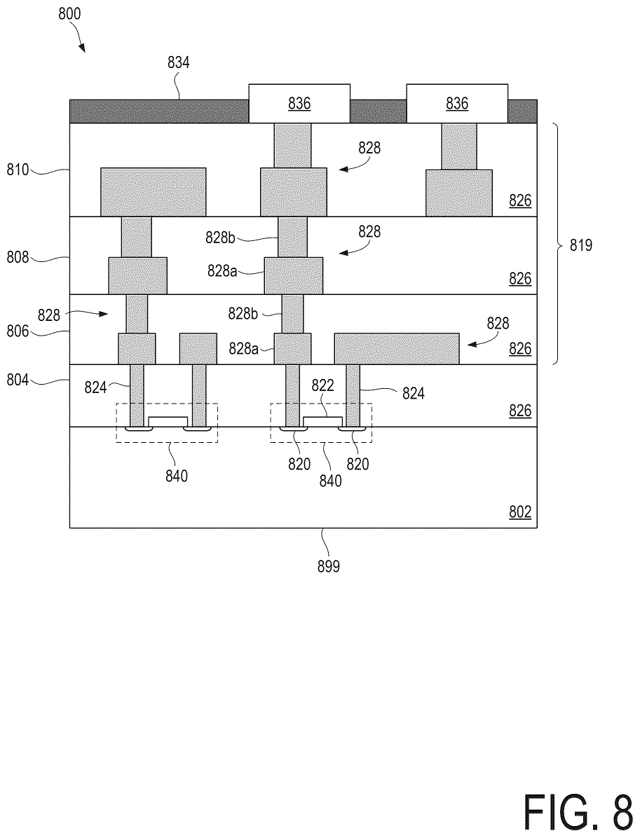

FIG. 8 is a cross-sectional view of an example integrated circuit structure 800 that may be included in any of the integrated circuit dies included in any of the integrated circuit components described herein. The integrated circuit structure 800 may be formed on a die substrate 802. In some embodiments, the die substrate 802 comprises bulk silicon. In some embodiments, the die substrate 802 comprises a silicon-on-insulator (SOI) substructure. In some embodiments, the die substrate 802 comprises alternative semiconductor materials, including group IV and/or group III-V materials, or combinations thereof.

A device layer 804 is disposed on the die substrate 802 and includes active devices such as transistors 840 (e.g., metal-oxide-semiconductor field effect transistors (MOSFETs)). The transistors 840 may include source and drain regions 820, a gate 822, and source and drain contacts 824 to couple the transistors 840 to overlying interconnect structures. The transistors 840 may include planar and/or non-planar device architectures (e.g., fin field effect transistor (FinFET) or gate-all-around field effect transistors (GAAFETs), complementary field effect transistors (CFETs)) and may include additional features not shown for clarity.

One or more interconnect layers 806-810 are disposed over the device layer 804 to route electrical signals to and from the transistors 840 and other circuitry. The interconnect layers 806-810 may collectively form a metallization stack 819 that includes dielectric material 826 and interconnect structures 828 (e.g., metal lines or metal traces 828a and vias 828b). In some embodiments, vias 828b electrically conductively couple lines or traces 828a in different ones of the interconnect layers 806, 808, and 810, and the metallization stack 819 may include any suitable number of interconnect layers.

In some embodiments, a solder resist material 834 and conductive contacts 836 are formed over the metallization stack 819 to provide external electrical connection points. In some embodiments, the integrated circuit structure 800 further includes a backside metallization stack (not shown) on a side of the die substrate 802 opposite the device layer 804, and through-substrate vias (e.g., TSVs) that extend through the die substrate 802 to provide electrical coupling between circuitry associated with the device layer 804 and/or metallization stack 819 and backside routing and/or backside conductive contacts (not shown). In such cases, the die substrate 802 can be thinned in connection with forming a backside metallization stack or other backside processing. In FIG. 8, the thermally conductive structures described herein can be attached to a backside surface 899 of the integrated circuit structure 800.

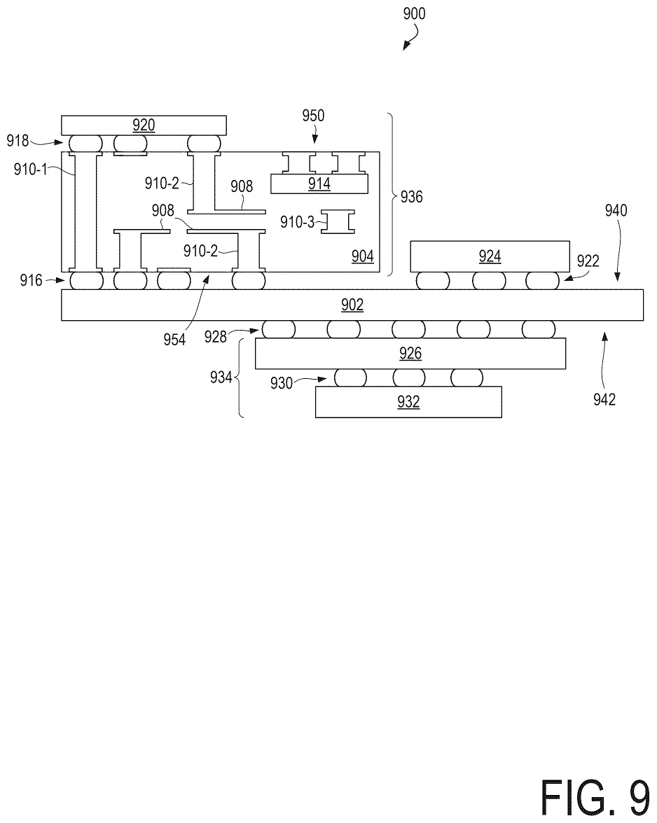

FIG. 9 is a cross-sectional view of an integrated circuit device assembly 900 that may include any of the integrated circuit components disclosed herein. The integrated circuit device assembly 900 includes a circuit board 902 (e.g., a motherboard or other system board) having components disposed on one or both of a first face 940 and an opposing second face 942. In some embodiments, circuit board 902 is a printed circuit board including multiple metal layers separated by dielectric material and interconnected by electrically conductive vias, and in other embodiments the circuit board 902 is another suitable substrate. The circuit board 902 can be any of the substrates (e.g., 136, 236, 336, 436) described herein.

In the example of FIG. 9, the integrated circuit device assembly 900 includes a package-on-interposer structure 936 coupled to the circuit board 902 by coupling components 916 (e.g., solder balls, pins, land grid array contacts, socket contacts, or other conductive contacts and/or mechanical attachment structures). The package-on-interposer structure 936 includes an integrated circuit component 920 coupled to an interposer 904 by coupling components 918. The interposer 904 can provide pitch translation and/or signal rerouting between the integrated circuit component 920 and the circuit board 902. The integrated circuit device assembly 900 may further include one or more additional integrated circuit components, such as an integrated circuit component 924 coupled to the circuit board 902 by coupling components 922.

The interposer 904 may be formed from any suitable material and may include metal interconnects 908 and vias, including through hole vias 910-1, blind vias 910-2, and buried vias 910-3, to provide electrical routing between a first face 950 and a second face 954 of the interposer 904. In some embodiments, the interposer 904 is a silicon interposer that includes through-silicon vias (TSVs) and one or more routing layers. In some embodiments, the interposer 904 further includes embedded devices 914, including passive and/or active devices.

In some embodiments, the interposer 904 and/or the circuit board 902 comprise a glass layer (e.g., a glass core or glass substrate). The glass layer may comprise an amorphous solid glass material such as silica, fused silica, aluminosilicate, borosilicate, or alumino-borosilicate, and may optionally include one or more additives to provide target mechanical, thermal, or electrical properties. In some embodiments, the glass layer is free of organic adhesive material (e.g., is not a glass-fiber/epoxy laminate). In some embodiments, the glass layer has a thickness in the range of about 50 microns to about 1.4 millimeters, and in some embodiments a multi-layer glass substrate includes individual glass layers having thicknesses in the range of about 25 microns to about 50 microns.

In some embodiments, redistribution layers (RDL) are located on one or both sides of the glass layer, and the glass layer includes through-glass vias (TGVs) to provide electrically conductive paths through the glass layer. In some embodiments, the glass layer has lateral dimensions suitable for interposer and/or circuit board applications (e.g., on the order of tens of millimeters to hundreds of millimeters), and the TGVs and/or other openings through the glass layer may be filled with metal to provide electrical interconnection.

In the example of FIG. 9, the integrated circuit device assembly 900 further includes a package-on-package structure 934 coupled to the second face 942 of the circuit board 902 by coupling components 928. The package-on-package structure 934 includes an integrated circuit component 926 and an integrated circuit component 932 coupled together by coupling components 930.

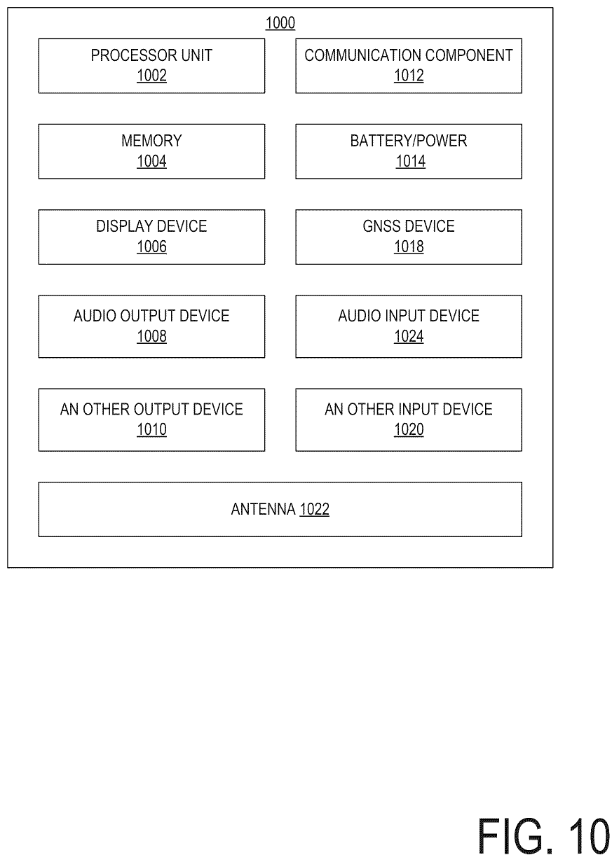

FIG. 10 is a block diagram of an example electrical device 1000 that may include any of the microelectronic assemblies disclosed herein, including the integrated circuit device assembly 900 and/or one or more integrated circuit components such as integrated circuit component 920. The electrical device 1000 may include one or more processor units 1002 and a memory 1004 coupled to the processor units 1002. In some embodiments, the processor units 1002 include one or more of a central processing unit (CPU), graphics processing unit (GPU), digital signal processor (DSP), application-specific integrated circuit (ASIC), field-programmable gate array (FPGA), neural network processing unit (NPU), data processor unit (DPU), or other accelerator. The memory 1004 may include volatile memory (e.g., dynamic random-access memory (DRAM), static random-access memory (SRAM)) and/or non-volatile memory (e.g., read-only memory (ROM), flash memory), and in some embodiments includes cache memory.

In some embodiments, the electrical device 1000 includes a communication component 1012 to manage communications. The communication component 1012 may support wireless communications and/or wired communications. Wireless communications may include, for example, Wi-Fi, Bluetooth, cellular communications, or other wireless protocols, and the electrical device 1000 may include an antenna 1022 to facilitate such wireless communications. Wired communications may include standards, such as Ethernet or other electrical and/or optical communication links.

In some embodiments, the electrical device 1000 further includes one or more input/output devices and/or corresponding interface circuitry, such as a display device 1006, an audio output device 1008, an additional output device 1010, and/or an audio input device 1024. In some embodiments, the electrical device 1000 includes a Global Navigation Satellite System (GNSS) device 1018 (e.g., a Global Positioning System (GPS) receiver) and one or more sensors, such as a compass, accelerometer, and/or gyroscope, which can be represented by another input device 1020. The electrical device 1000 further includes a battery or other power supply 1014. The electrical device 1000 may have any suitable form factor, including a handheld device, a wearable device, a desktop computer, a server, or a rack-level computing solution.

As used herein, the term “connected” may indicate elements are in direct physical or electrical contact with each other and the term “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, positions, dimensions, shapes, surface profiles (e.g., planarity), functional performance, and other properties that vary slightly from the meaning of the unmodified term, such as variations attributable to expected manufacturing tolerances, assembly variation, and/or measurement uncertainty. For example, layers, faces, or features that are referred to as being substantially parallel can refer to layers, faces, or features that are within +/−10 degrees of being parallel with each other, and layers, faces, or features that are referred to as being substantially perpendicular to each other can refer to features that are within +/−15 degrees of being perpendicular to each other. As used herein, values are “substantially different” when a difference between the values is greater than expected manufacturing and measurement variation, such that tolerance ranges associated with the values do not overlap. As used herein, values are “substantially equal” or “substantially the same” when any difference between the values is within expected manufacturing and measurement variation, such that tolerance ranges associated with the values overlap and/or the values do not differ in a manner that materially affects intended operation. As used herein, a surface described as “substantially flat” includes a surface that may have minor non-planarities (e.g., warpage, bow, dishing, waviness, or roughness) consistent with expected manufacturing, assembly, and/or operational conditions, but that is sufficiently planar for its intended sealing, mounting, or thermal function. As used herein, a seal or coupling described as configured to “substantially prevent leakage” includes a seal or coupling that may permit minor leakage consistent with expected manufacturing and operating conditions, but that reduces leakage to a level that does not materially affect intended coolant routing and/or thermal performance of the apparatus during normal operation.

Values modified by the word “about” include values within +/−10% of the listed values and values listed as being within a range include those within a range from 10% less than the listed lower range limit and 10% greater than the listed higher range limit.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are arranged next to each other (e.g., side-by-side, top and bottom).

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the phrase “electrically conductively coupled” refers to the presence of one or more electrically conductive paths between components that are recited as being electrically conductively coupled.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Further, as used in this application and the claims, a list of items joined by the term “one or more of” can mean any combination of the listed terms. For example, the phrase “one or more of A, B, and C” can mean A; B; C; A and B; A and C; B and C; or A, B, and C. Moreover, as used in this application and the claims, a list of items joined by the term “one of” can mean any one of the listed terms. For example, the phrase “one of A, B, or C” can mean A, B, or C.

As used in this application and the claims, the phrase “individual of” or “respective of” followed by a list of items recited or stated as having a trait, feature, etc. means that all of the items in the list possess the stated or recited trait, feature, etc. For example, the phrase “individual of A, B, or C, comprises a sidewall” or “respective of A, B, or C, comprises a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a substrate; an integrated circuit component on the substrate; a lid structure over the integrated circuit component, wherein the lid structure comprises a top portion and a sidewall, the sidewall extends from the top portion in a direction toward the substrate, the sidewall extends around the integrated circuit component, and the lid structure and the substrate define a cavity within which the integrated circuit component is located; an inlet port extending through the top portion; an outlet port extending through the top portion; an inner surface of the top portion facing opposite a surface of the integrated circuit component; and a plurality of thermally conductive structures in the cavity, the plurality of thermally conductive structures extending from the surface of the integrated circuit component toward the inner surface of the top portion.

Example 2 comprises the apparatus of example 1, wherein the inlet port and the outlet port are spaced along a direction parallel to the surface of the integrated circuit component, and the plurality of thermally conductive structures are located between the inlet port and the outlet port along the direction.

Example 3 comprises the apparatus of example 1 or 2, wherein at least one of the plurality of thermally conductive structures touches the inner surface of the top portion.

Example 4 comprises the apparatus of any one of examples 1-3, wherein at least one of the plurality of thermally conductive structures is spaced from the inner surface of the top portion by a gap.

Example 5 comprises the apparatus of any one of examples 1-4, wherein at least one thermally conductive structure of the plurality of thermally conductive structures comprises a solder material.

Example 6 comprises the apparatus of example 5, wherein the at least one thermally conductive structure is substantially ball-shaped.

Example 7 comprises the apparatus of any one of examples 1-4, wherein at least one thermally conductive structure of the plurality of thermally conductive structures comprises a pillar comprising a solder body at a distal end of the pillar.

Example 8 comprises the apparatus of example 7, wherein the solder body is distal to the surface of the integrated circuit component.

Example 9 comprises the apparatus of example 7, wherein the solder body touches the inner surface of the top portion.

Example 10 comprises the apparatus of any one of examples 1-4, wherein at least one thermally conductive structure of the plurality of thermally conductive structures is pillar-shaped.

Example 11 comprises the apparatus of any one of examples 1-10, wherein at least one thermally conductive structure of the plurality of thermally conductive structures comprises a pin comprising a metal.

Example 12 comprises the apparatus of example 11, wherein the metal is copper.

Example 13 comprises the apparatus of any one of examples 1-4, wherein a first thermally conductive structure of the plurality of thermally conductive structures comprises a pillar comprising a solder body at a distal end of the pillar and a second thermally conductive structure of the plurality of thermally conductive structures comprises a pin.

Example 14 comprises the apparatus of any one of examples 1-4, wherein at least one thermally conductive structure of the plurality of thermally conductive structures comprises a solder material layer on the surface of the integrated circuit component, the solder material layer comprising a pattern.

Example 15 comprises the apparatus of example 14, wherein the pattern comprises a grid pattern comprising solder material segments separated by openings.

Example 16 comprises the apparatus of any one of examples 1-15, further comprising a plurality of coupling components between the integrated circuit component and the substrate.

Example 17 comprises the apparatus of example 16, further comprising an underfill material at least partially positioned between the integrated circuit component and the substrate, the underfill material encompassing the plurality of coupling components.

Example 18 comprises the apparatus of example 17, wherein the integrated circuit component comprises a device layer and a metallization stack, and wherein the metallization stack is positioned between the plurality of coupling components and the device layer.

Example 19 comprises the apparatus of example 18, wherein a metal trace of the metallization stack is electrically conductively coupled to a metal trace of the substrate at least in part by a coupling component of the plurality of coupling components.

Example 20 comprises the apparatus of any one of examples 1-19, further comprising a seal positioned between the sidewall and the substrate, the seal surrounding the cavity.

Example 21 comprises the apparatus of any one of examples 1-20, wherein the sidewall comprises a polymer material.

Example 22 comprises the apparatus of any one of examples 1-21, wherein the plurality of thermally conductive structures is arranged in a grid comprising a plurality of rows and a plurality of columns.

Example 23 comprises the apparatus of any one of examples 1-21, wherein the plurality of thermally conductive structures is arranged in a staggered grid comprising a plurality of rows, wherein thermally conductive structures of a first row are offset from thermally conductive structures of an adjacent second row.

Example 24 comprises the apparatus of any one of examples 1-23, wherein the plurality of thermally conductive structures comprise a first subset in a first region of the surface of the integrated circuit component and a second subset in a second region of the surface of the integrated circuit component, the first subset is arranged with a first pitch, and the second subset is arranged with a second pitch different from the first pitch.

Example 25 comprises the apparatus of example 24, wherein at least one of the first pitch, the second pitch, a size of the thermally conductive structures in the first subset, or a size of the thermally conductive structures in the second subset is selected based on an expected heat generation distribution of the integrated circuit component.

Example 26 comprises the apparatus of any one of examples 1-25, wherein the apparatus further comprises a nozzle, the nozzle comprising an orifice in the top portion, and the orifice opens toward the surface of the integrated circuit component.

Example 27 comprises the apparatus of any one of examples 1-25, wherein the apparatus further comprises a plurality of nozzles, individual nozzles of the plurality of nozzles comprising an orifice in the top portion that opens toward the surface of the integrated circuit component, and wherein at least one thermally conductive structure of the plurality of thermally conductive structures is located between adjacent nozzles of the plurality of nozzles.

Example 28 comprises the apparatus of example 1, wherein the plurality of thermally conductive structures is a first plurality of thermally conductive structures, the inlet port is a first inlet port, and the outlet port is a first outlet port, the apparatus further comprising: a second integrated circuit component on the substrate; a second lid structure over the second integrated circuit component, wherein the second lid structure comprises a second top portion and a second sidewall, the second sidewall extending from the second top portion toward the substrate, and the second lid structure and the substrate define a second cavity within which the second integrated circuit component is located; a second inlet port extending through the second top portion; a second outlet port extending through the second top portion; and a second plurality of thermally conductive structures in the second cavity, the second plurality of thermally conductive structures extending from a surface of the second integrated circuit component toward an inner surface of the second top portion.

Example 29 comprises the apparatus of example 28, wherein the second plurality of thermally conductive structures comprises solder bodies, pins, pillars comprising a solder body at a distal end of the individual pillars, or a solder material layer on the surface of the second integrated circuit component, the solder material layer comprising a pattern.

Example 30 comprises the apparatus of example 28, wherein a first pitch between adjacent thermally conductive structures of the first plurality of thermally conductive structures is different from a second pitch between adjacent thermally conductive structures of the second plurality of thermally conductive structures.

Example 31 comprises the apparatus of example 28, wherein a first maximum lateral dimension of a thermally conductive structure of the first plurality of thermally conductive structures, measured parallel to the surface of the integrated circuit component, is substantially different from a second maximum lateral dimension of a thermally conductive structure of the second plurality of thermally conductive structures, measured parallel to the surface of the second integrated circuit component.

Example 32 comprises the apparatus of example 28, wherein a first height of a thermally conductive structure of the first plurality of thermally conductive structures, measured from the surface of the integrated circuit component to a distal end of the thermally conductive structure, is substantially different from a second height of a thermally conductive structure of the second plurality of thermally conductive structures, measured from the surface of the second integrated circuit component to a distal end of the thermally conductive structure.

Example 33 is a device comprising: a substrate; a first integrated circuit component on the substrate; a second integrated circuit component on the substrate; a lid structure over the first integrated circuit component and the second integrated circuit component, wherein the lid structure comprises a top portion and a sidewall, the sidewall extending from the top portion toward the substrate, and the lid structure and the substrate define a cavity within which the first integrated circuit component and the second integrated circuit component are located; a first inlet port extending through the top portion; a first outlet port extending through the top portion; an inner surface of the top portion facing opposite a first surface of the first integrated circuit component and facing opposite a second surface of the second integrated circuit component; a first plurality of thermally conductive structures in the cavity, the first plurality of thermally conductive structures extending from the first surface toward the inner surface; and a second plurality of thermally conductive structures in the cavity, the second plurality of thermally conductive structures extending from the second surface toward the inner surface.

Example 34 comprises the device of example 33, wherein the first integrated circuit component comprises a first height from the substrate to the first surface, and wherein the second integrated circuit component comprises a second height from the substrate to the second surface different from the first height.

Example 35 comprises the device of example 33, wherein the first plurality of thermally conductive structures have a first height, and the second plurality of thermally conductive structures have a second height different from the first height.

Example 36 comprises the device of example 33, wherein a first structure height of a thermally conductive structure of the first plurality of thermally conductive structures, measured from the first surface to a distal end of the thermally conductive structure, is substantially equal to a second structure height of a thermally conductive structure of the second plurality of thermally conductive structures, measured from the second surface to a distal end of the thermally conductive structure.

Example 37 comprises the device of example 33, wherein a first distance between the inner surface and the first surface is substantially equal to a second distance between the inner surface and the second surface.

Example 38 comprises the device of any one of examples 33-37, wherein the lid structure comprises a second inlet port and a second outlet port extending through the top portion.

Example 39 comprises the device of any one of examples 33-38, wherein the first integrated circuit component is adjacent to a first side of the second integrated circuit component, the device further comprises a third integrated circuit component located in the cavity, and the third integrated circuit component is adjacent to a second side of the first integrated circuit component.

Example 40 comprises the device of any one of examples 33-39, wherein the first plurality of thermally conductive structures comprises a plurality of solder bodies.

Example 41 comprises the device of any one of examples 33-39, wherein the first plurality of thermally conductive structures comprises a plurality of pins.

Example 42 comprises the device of any one of examples 33-39, wherein the first plurality of thermally conductive structures comprises a plurality of pillars, individual pillars comprising a solder body at a distal end of the pillar.

Example 43 comprises the device of any one of examples 33-39, wherein the first plurality of thermally conductive structures comprises a solder material layer on the first surface, the solder material layer comprising a pattern.

Example 44 comprises the device of any one of examples 33-39, wherein the first plurality of thermally conductive structures is of a first type selected from solder bodies, pins, pillars comprising solder bodies at a distal end of the pillar, and a solder material layer comprising a pattern, wherein the second plurality of thermally conductive structures is of a second type selected from solder bodies, pins, pillars comprising solder bodies at a distal end of the pillar, and a solder material layer comprising a pattern, and wherein the first type is different from the second type.

Example 45 comprises the device of any one of examples 35-44, wherein a first maximum lateral dimension of a thermally conductive structure of the first plurality of thermally conductive structures, measured parallel to the first surface, is substantially different from a second maximum lateral dimension of a thermally conductive structure of the second plurality of thermally conductive structures, measured parallel to the second surface.

Example 46 comprises the device of any one of examples 35-45, wherein the substrate is a printed circuit board.

Example 47 comprises the device of example 46, further comprising a battery electrically conductively coupled to the printed circuit board.

Example 48 comprises the device of any one of examples 35-47, further comprising a housing that encloses the substrate and the lid structure.

Example 49 is a system comprising: a substrate; a first integrated circuit component on the substrate; a first lid structure over the first integrated circuit component, wherein the first lid structure comprises a first top portion and a first sidewall, the first sidewall extending from the first top portion toward the substrate, and the first lid structure and the substrate define a first cavity within which the first integrated circuit component is located; a first inlet port extending through the first top portion; a first outlet port extending through the first top portion; a first plurality of thermally conductive structures in the first cavity, the first plurality of thermally conductive structures extending from a surface of the first integrated circuit component toward an inner surface of the first top portion; a second integrated circuit component on the substrate; a second lid structure over the second integrated circuit component, wherein the second lid structure comprises a second top portion and a second sidewall, the second sidewall extending from the second top portion toward the substrate, and the second lid structure and the substrate define a second cavity within which the second integrated circuit component is located; a second inlet port extending through the second top portion; a second outlet port extending through the second top portion; and a second plurality of thermally conductive structures in the second cavity, the second plurality of thermally conductive structures extending from a surface of the second integrated circuit component toward an inner surface of the second top portion.

Example 50 comprises the system of example 49, further comprising: a pump; a heat exchanger; and one or more fluid conduits fluidically coupled to the pump, the heat exchanger, the first inlet port, the first outlet port, the second inlet port, and the second outlet port.

Example 51 comprises the system of example 49 or 50, wherein the first lid structure and the second lid structure do not share a sidewall, and wherein the first lid structure is separate from the second lid structure.

Example 52 comprises the system of any one of examples 49-51, further comprising a housing that encloses the first lid structure and the second lid structure.

Example 53 comprises the system of any one of examples 49-51, wherein the first plurality of thermally conductive structures comprises a plurality of solder bodies, pins, or pillars comprising a solder body at a distal end of the individual pillars, or a solder material layer on the surface of the first integrated circuit component, the solder material layer comprising a pattern.

Example 54 comprises the system of any one of examples 49-53, wherein the second plurality of thermally conductive structures comprises a plurality of solder bodies, pins, or pillars comprising a solder body at a distal end of the individual pillars, or a solder material layer on the surface of the second integrated circuit component, the solder material layer comprising a pattern.

Example 55 comprises the system of any one of examples 49-53, wherein a first maximum lateral dimension of a thermally conductive structure of the first plurality of thermally conductive structures, measured parallel to the surface of the first integrated circuit component, is different from a second maximum lateral dimension of a thermally conductive structure of the second plurality of thermally conductive structures, measured parallel to the surface of the second integrated circuit component.

Example 56 comprises the system of any one of examples 49-54, wherein a first height of a thermally conductive structure of the first plurality of thermally conductive structures, measured from the surface of the first integrated circuit component to a distal end of the thermally conductive structure, is different from a second height of a thermally conductive structure of the second plurality of thermally conductive structures, measured from the surface of the second integrated circuit component to a distal end of the thermally conductive structure.

Example 57 is an apparatus comprising: a substrate; an integrated circuit component on the substrate; a lid structure over the integrated circuit component, wherein the lid structure comprises a top portion and a sidewall, the sidewall extending from the top portion toward the substrate, and the lid structure and the substrate define a cavity within which the integrated circuit component is located; an inlet port extending through the top portion; an outlet port extending through the top portion; and a heat transfer means for transferring heat from the integrated circuit component to a coolant that is to flow through the cavity during operation of the integrated circuit component.

Example 58 is a method comprising: forming a plurality of thermally conductive structures on a surface of an integrated circuit component attached to a substrate; and after forming the plurality of thermally conductive structures, attaching a lid structure to the substrate over the integrated circuit component, the lid structure comprising a top portion and a sidewall, the top portion comprising an inlet port and an outlet port, wherein the lid structure and the substrate define a cavity within which the integrated circuit component is located.

Example 59 comprises the method of example 58, wherein forming the plurality of thermally conductive structures comprises: forming a mask on the surface of the integrated circuit component, the mask comprising a plurality of openings that expose portions of the surface of the integrated circuit component; forming a layer comprising iridium on the portions of the surface of the integrated circuit component; forming a layer comprising gold on the layer comprising iridium; removing the mask, wherein a plurality of pillar-shaped structures remains on the surface of the integrated circuit component after removing the mask, individual pillar-shaped structures of the plurality of pillar-shaped structures comprising a layer comprising gold on a layer comprising iridium; forming a plurality of solder balls on distal ends of the pillar-shaped structures that are distal to the integrated circuit component; and reflowing the plurality of solder balls to form solder bodies at the distal ends of the individual pillar-shaped structures.

Example 60 comprises the method of example 59, wherein attaching the lid structure results in the solder body of at least one of the pillar-shaped structures touching an inner surface of the lid structure.

Example 61 comprises the method of example 58, wherein forming the plurality of thermally conductive structures comprises forming a plurality of pins on the surface of the integrated circuit component.

Example 62 comprises the method of example 58, wherein forming the plurality of thermally conductive structures comprises forming a solder material layer on the surface of the integrated circuit component.

Example 63 comprises the method of example 62, wherein forming the solder material layer comprises depositing solder material on the surface through a mask to form solder material segments separated by openings.

Example 64 comprises the method of any one of examples 58-63, wherein attaching the lid structure comprises forming a seal between the sidewall and the substrate, the seal surrounding the cavity.

Example 65 is a method comprising: providing the apparatus of example 1; operating the integrated circuit component; and pumping a coolant through the cavity from the inlet port to the outlet port.

Example 66 comprises the method of example 65, wherein pumping the coolant comprises operating a pump to drive the coolant through one or more fluid conduits fluidically coupled to the inlet port and the outlet port.

Example 67 comprises the method of example 65 or 66, wherein the plurality of thermally conductive structures comprise solder bodies, pins, pillars comprising a solder body at a distal end of the individual pillars, or a solder material layer on the surface of the integrated circuit component, the solder material layer comprising a pattern.

1. An apparatus comprising:
a substrate;
an integrated circuit component on the substrate;
a lid structure over the integrated circuit component, wherein the lid structure comprises a top portion and a sidewall, the sidewall extending from the top portion in a direction toward the substrate and extending around the integrated circuit component, and the lid structure and the substrate define a cavity within which the integrated circuit component is located;
an inlet port extending through the top portion;
an outlet port extending through the top portion;
an inner surface of the top portion facing opposite a surface of the integrated circuit component; and
a plurality of thermally conductive structures in the cavity, the plurality of thermally conductive structures extending from the surface of the integrated circuit component toward the inner surface of the top portion.

2. The apparatus of claim 1, wherein at least one thermally conductive structure of the plurality of thermally conductive structures is substantially ball-shaped and comprises a solder material.

3. The apparatus of claim 1, wherein at least one thermally conductive structure of the plurality of thermally conductive structures comprises a pillar comprising a solder body at a distal end of the pillar, the distal end being distal to the surface of the integrated circuit component.

4. The apparatus of claim 1, wherein at least one thermally conductive structure of the plurality of thermally conductive structures comprises a pin comprising a metal.

5. The apparatus of claim 1, wherein at least one thermally conductive structure of the plurality of thermally conductive structures comprises a solder material layer on the surface of the integrated circuit component, the solder material layer comprising a pattern.

6. The apparatus of claim 1, wherein the plurality of thermally conductive structures comprise a first subset in a first region of the surface of the integrated circuit component and a second subset in a second region of the surface of the integrated circuit component, the first subset is arranged at a first pitch between adjacent thermally conductive structures, and the second subset is arranged at a second pitch between adjacent thermally conductive structures, the second pitch being different from the first pitch.

7. The apparatus of claim 6, wherein the first pitch is less than the second pitch and the first region is associated with a hotspot region having a higher expected heat generation than the second region.

8. The apparatus of claim 1, wherein the apparatus further comprises a plurality of nozzles, individual nozzles of the plurality of nozzles comprising an orifice in the top portion that opens toward the surface of the integrated circuit component, and wherein at least one thermally conductive structure of the plurality of thermally conductive structures is located between adjacent nozzles of the plurality of nozzles.

9. The apparatus of claim 1, wherein the plurality of thermally conductive structures is a first plurality of thermally conductive structures, the inlet port is a first inlet port, and the outlet port is a first outlet port, the apparatus further comprising:
a second integrated circuit component on the substrate;
a second lid structure over the second integrated circuit component, wherein the second lid structure comprises a second top portion and a second sidewall, the second sidewall extending from the second top portion toward the substrate, and the second lid structure and the substrate define a second cavity within which the second integrated circuit component is located;
a second inlet port extending through the second top portion;
a second outlet port extending through the second top portion; and
a second plurality of thermally conductive structures in the second cavity, the second plurality of thermally conductive structures extending from a surface of the second integrated circuit component toward an inner surface of the second top portion.

10. The apparatus of claim 9, wherein a first height of a thermally conductive structure of the first plurality of thermally conductive structures, measured from the surface of the integrated circuit component to a distal end of the thermally conductive structure, is substantially different from a second height of a thermally conductive structure of the second plurality of thermally conductive structures, measured from the surface of the second integrated circuit component to a distal end of the thermally conductive structure.

11. A device comprising:
a substrate;
a first integrated circuit component on the substrate;
a second integrated circuit component on the substrate;
a lid structure over the first integrated circuit component and the second integrated circuit component, wherein the lid structure comprises a top portion and a sidewall, the sidewall extending from the top portion toward the substrate, and the lid structure and the substrate define a cavity within which the first integrated circuit component and the second integrated circuit component are located;
a first inlet port extending through the top portion;
a first outlet port extending through the top portion;
an inner surface of the top portion facing opposite a first surface of the first integrated circuit component and facing opposite a second surface of the second integrated circuit component;
a first plurality of thermally conductive structures in the cavity, the first plurality of thermally conductive structures extending from the first surface toward the inner surface; and
a second plurality of thermally conductive structures in the cavity, the second plurality of thermally conductive structures extending from the second surface toward the inner surface.

12. The device of claim 11, wherein the first plurality of thermally conductive structures have a first height measured from the first surface to respective distal ends of the thermally conductive structures, and the second plurality of thermally conductive structures have a second height measured from the second surface to respective distal ends of the thermally conductive structures, the second height being different from the first height.

13. The device of claim 11, wherein a first structure height of a thermally conductive structure of the first plurality of thermally conductive structures, measured from the first surface to a distal end of the thermally conductive structure, is substantially equal to a second structure height of a thermally conductive structure of the second plurality of thermally conductive structures, measured from the second surface to a distal end of the thermally conductive structure.

14. The device of claim 11, wherein a first distance between the inner surface and the first surface is substantially equal to a second distance between the inner surface and the second surface.

15. The device of claim 12, wherein the first plurality of thermally conductive structures comprises a plurality of solder bodies, a plurality of pins, or a plurality of pillars, individual pillars of the plurality of pillars comprising a solder body at a distal end of the pillar.

16. The device of claim 11, wherein the substrate is a printed circuit board.

17. A system comprising:
a substrate;
a first integrated circuit component on the substrate;
a first lid structure over the first integrated circuit component, wherein the first lid structure comprises a first top portion and a first sidewall, the first sidewall extending from the first top portion toward the substrate, and the first lid structure and the substrate define a first cavity within which the first integrated circuit component is located;
a first inlet port extending through the first top portion;
a first outlet port extending through the first top portion;
a first plurality of thermally conductive structures in the first cavity, the first plurality of thermally conductive structures extending from a surface of the first integrated circuit component toward an inner surface of the first top portion;
a second integrated circuit component on the substrate;
a second lid structure over the second integrated circuit component, wherein the second lid structure comprises a second top portion and a second sidewall, the second sidewall extending from the second top portion toward the substrate, and the second lid structure and the substrate define a second cavity within which the second integrated circuit component is located;
a second inlet port extending through the second top portion;
a second outlet port extending through the second top portion; and
a second plurality of thermally conductive structures in the second cavity, the second plurality of thermally conductive structures extending from a surface of the second integrated circuit component toward an inner surface of the second top portion.

18. The system of claim 17, further comprising:
a pump;
a heat exchanger; and
one or more fluid conduits fluidically coupled to the pump, the heat exchanger, the first inlet port, the first outlet port, the second inlet port, and the second outlet port.

19. The system of claim 17, wherein a first maximum lateral dimension of a thermally conductive structure of the first plurality of thermally conductive structures, measured parallel to the surface of the first integrated circuit component, is substantially different from a second maximum lateral dimension of a thermally conductive structure of the second plurality of thermally conductive structures, measured parallel to the surface of the second integrated circuit component.

20. The system of claim 17, wherein a first height of a thermally conductive structure of the first plurality of thermally conductive structures, measured from the surface of the first integrated circuit component to a distal end of the thermally conductive structure, is substantially different from a second height of a thermally conductive structure of the second plurality of thermally conductive structures, measured from the surface of the second integrated circuit component to a distal end of the thermally conductive structure.
